(19) United States
(12) Patent Application Publication
(10) Pub. No.: US 2018/0294139 A1
(43) Pub. Date: Oct. 11, 2018

(54) GAS PHASE PARTICLE REDUCTION IN PECVD CHAMBER

(71) Applicant: Applied Materials, Inc., Santa Clara, CA (US)

(72) Inventors: Bhaskar KUMAR, Santa Clara, CA (US); Sidharth BHATIA, Santa Cruz, CA (US); Anup Kumar SINGH, Santa Clara, CA (US); Vivek Bharat SHAH, Sunnyvale, CA (US); Ganesh BALASUBRAMANIAN, Sunnyvale, CA (US)

(21) Appl. No.: 15/945,413

(22) Filed: Apr. 4, 2018

Related U.S. Application Data
(60) Provisional application No. 62/483,244, filed on Apr. 7, 2017.

(51) Int. Cl. H01J 37/32; H01L 21/02; H01L 21/285; C23C 16/52

(52) U.S. Cl. CPC H01J 37/32137; H01L 21/0262; H01L 21/02274; H01L 21/28556; H01J 37/3244; C23C 16/503; H01J 37/32568; H01J 37/32541; C23C 16/52; H01J 2237/3321; H01J 37/32082

(57) ABSTRACT

The present disclosure relates to methods and apparatus for reducing particle contamination on substrates in a plasma process chamber. In one embodiment, by applying a DC power to an electrode surrounding a processing region, the boundary of a plasma region formed in the processing region extends closer to the chamber body and outside of the diameter of the substrate support. In another embodiment, by applying a negative bias to an electrode or a positive bias to the lid, negatively charged species located at the boundary of the plasma region are lifted by the electrostatic force created by the negative bias or the positive bias. As a result, species located at the boundary of the plasma region will not fall onto the edge of the substrate disposed on the substrate support as the electric power for sustaining the plasma region is turned off, leading to reduced particle contamination on the substrate.

### CROSS-REFERENCE TO RELATED APPLICATIONS

This application claims benefit of U.S. Provisional Patent Applications, Ser. No. 62/483,244, filed Apr. 7, 2017, which is incorporated herein by reference.

### BACKGROUND

### Field

Embodiments of the present disclosure generally relate to methods and apparatus for reducing particle contamination on substrates in a plasma process chamber.

### Description of the Related Art

Plasma-enhanced chemical vapor deposition (PECVD) process is a chemical process where electro-magnetic energy is applied to at least one precursor gas or precursor vapor to transform the precursor into a reactive plasma. There are many advantages in using PECVD, including but not limited to lowering the temperature required to form a film, increasing the rate of formation of the film, enhancing the properties of the layers being formed. Particles of the gas or vapor ionized by the plasma diffuse through the plasma sheath and are absorbed onto the substrate to form a thin film layer. Plasma may be generated inside the processing chamber, i.e., in-situ, or in a remote plasma generator that is remotely positioned from the processing chamber. PECVD is widely used to deposit materials on substrates to produce high-quality and high-performance semiconductor devices.

Particle contamination during plasma processes such as PECVD is a major impediment to the deposition and etching of thin films during the production of semiconductor devices. Therefore, improved methods and apparatus are needed for reducing particle contamination in a plasma processing chamber.

### SUMMARY

Embodiments of the present disclosure generally relate to methods and apparatus for reducing particle contamination on substrates in a plasma process chamber. In one embodiment, a method includes forming a plasma region in a processing region of a process chamber and extending a boundary of the plasma region to be outside of a diameter of a substrate support by biasing an electrode disposed radially outward of the plasma region.

In another embodiment, a method including forming a plasma region in a processing region of a process chamber, applying a negative bias to a first electrode embedded in a substrate support, and continuing the negative bias to the first electrode after an electric power utilized to sustain the plasma region is turned off.

In another embodiment, a method including forming a plasma region in a processing region of a process chamber, applying a positive bias to a lid, and continuing the positive bias to the lid after an electric power utilized to sustain the plasma region is turned off.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic cross-sectional view of a plasma process chamber according to one embodiment described herein.

FIG. 2 is a schematic cross-sectional view of a plasma process chamber according to another embodiment described herein.

FIG. 3 is a flow chart of a method for reducing particle contamination in a plasma process chamber according to one embodiment described herein.

FIG. 4 is a flow chart of a method for reducing particle contamination in a plasma process chamber according to another embodiment described herein.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

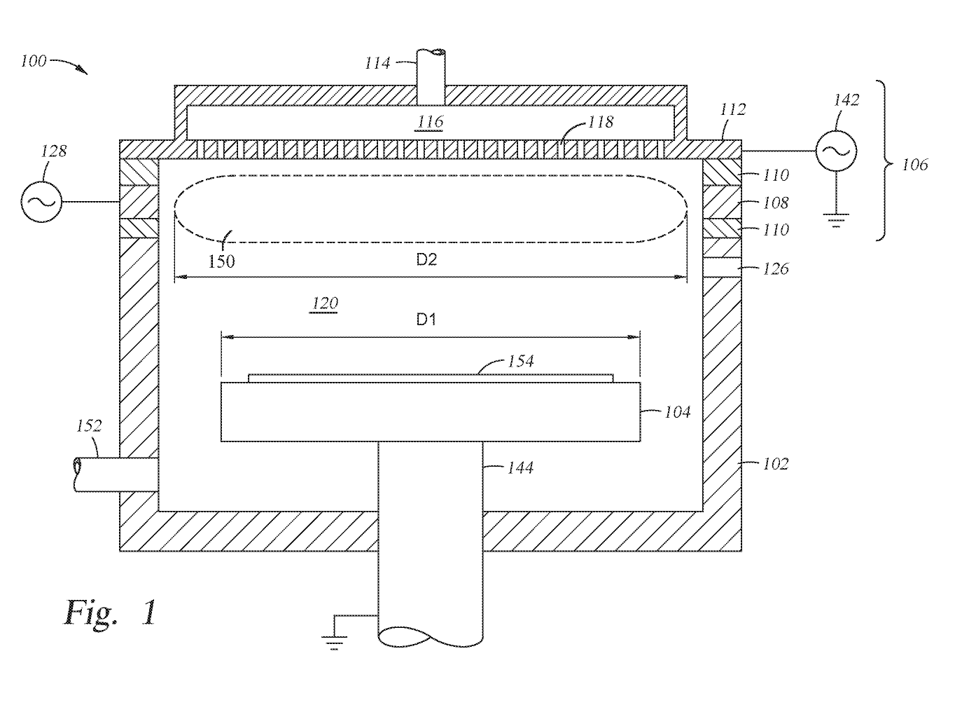

FIG. 1 is a schematic cross-sectional view of a plasma process chamber 100 according to one embodiment described herein. The process chamber 100 may be a plasma enhanced chemical vapor deposition (PECVD) chamber or other plasma enhanced process chamber. An exemplary process chamber which may benefit from the embodiments described herein is the PRODUCER® series of PECVD enabled chambers, available from Applied Materials, Inc., Santa Clara, Calif. It is contemplated that other similarly equipped process chambers from other manufacturers may also benefit from the embodiments described herein. The process chamber 100 includes a chamber body 102, a substrate support 104 disposed inside the chamber body 102, and a lid assembly 106 coupled to the chamber body 102 and enclosing the substrate support 104 in a processing region 120. The lid assembly 106 includes a gas distributor 112. Substrates 154 are provided to the processing region 120 through an opening 126 formed in the chamber body 102.

An electrode 108 is disposed adjacent to the chamber body 102 and separating the chamber body 102 from other components of the lid assembly 106. The electrode 108 may be part of the lid assembly 106, or may be a separate side wall electrode. The electrode 108 may be an annular member, or a ring-like member, and may be a ring electrode. The electrode 108 may be a continuous loop around a circumference of the process chamber 100 surrounding the processing region 120, or may be discontinuous at selected locations if desired. The electrode 108 may also be a perforated electrode, such as a perforated ring or a mesh electrode. The electrode 108 may also be a plate electrode, for example a secondary gas distributor. The electrode 108 may be coupled to a DC power source 128 for extending the boundary of a plasma region 150 formed in the processing region 120. The plasma region 150 is defined as the region occupied by the plasma formed in the processing region 120.

An isolator 110, which may be a dielectric material such as a ceramic or metal oxide, for example aluminum oxide and/or aluminum nitride, contacts the electrode 108 and separates the electrode 108 electrically and thermally from the gas distributor 112 and from the chamber body 102. The gas distributor 112 features openings 118 for admitting process gases into the processing region 120. The process gases may be supplied to the process chamber 100 via a conduit 114, and the process gases may enter a gas mixing region 116 prior to flowing through the openings 118. The gas distributor 112 is coupled to an electric power source 142, such as an RF generator or a DC power source. The DC power source may supply continuous and/or pulsed DC power to the gas distributor 112. The RF generator may supply continuous and/or pulsed RF power to the gas distributor 112. The electric power 142 is turned on during the operation to supply an electric power to the gas distributor 112 to facilitate formation of a plasma region 150 in the processing region 120.

The substrate support 104 may be formed from a metallic or ceramic material, for example a metal oxide or nitride or oxide/nitride mixture such as aluminum, aluminum oxide, aluminum nitride, or an aluminum oxide/nitride mixture. The substrate support 104 is supported by a shaft 144. The substrate support 104 may be grounded. The substrate support 104 has a diameter D1 (or a width if the substrate support 104 is not circular). An electrode (not shown) may be embedded in the substrate support 104 to facilitate formation of the plasma region 150. For example, the electrode embedded within the substrate support and the powered gas distributor 112 may facilitate formation of a capacitively-coupled plasma. An exhaust 152 is formed in the chamber body 102 at a location below the substrate support 104. The exhaust 152 may be connected to a vacuum pump (not shown) to remove unreacted species and by-products from the processing chamber 100.

The lid assembly 106 including the electrode 108 shown in FIG. 1 may be used with any processing chamber for plasma processing. Chambers from other manufacturers may also be used with the components described above.

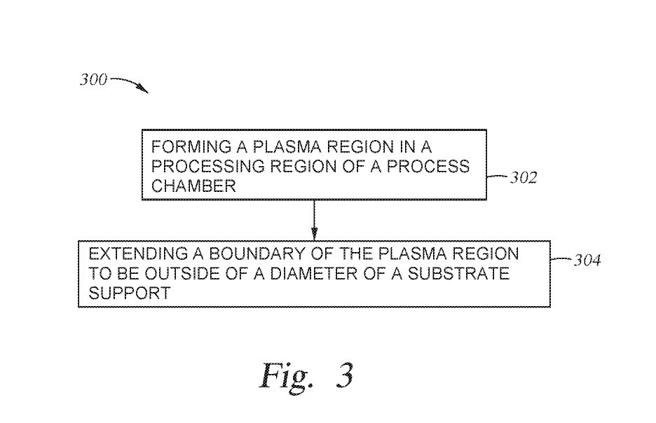

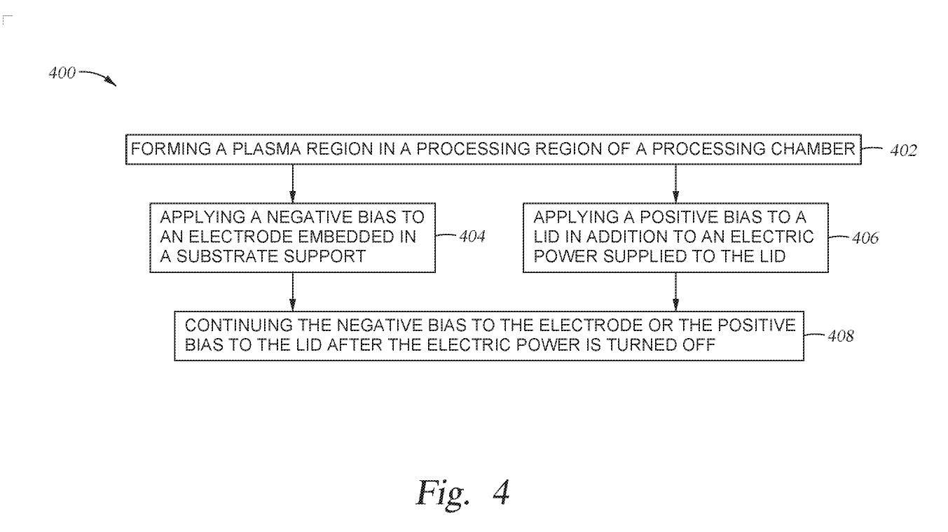

During operation, the plasma region 150 initially formed in the processing region 120 of the process chamber 100 has a distance between locations on the boundary of the plasma region 150 closest to the chamber body 102, and the distance is within the diameter D1 of the substrate support 104. In other words, the boundary of the plasma region 150 initially formed in the processing region 120 is within the diameter D1 of the substrate support 104 and does not extend outside of the diameter D1 of the substrate support 104. After the electric power source 142 is turned off, the electric field created by the electric power disappears, and the plasma region 150 dissipates radially outward. Because the electric field has disappeared, the negatively charged species located at the boundary of the plasma region 150 are attracted to the positively charged layer deposited on the substrate 154 due to the electrostatic force. Since the boundary of the plasma region 150 in the processing region 120 is within the substrate support 104, the negatively charged species fall on the edge of the substrate 154 when the electric power source 142 is turned off. The negatively charged species create particle contamination on the edge of the substrate 154. FIGS. 3 and 4 describe methods for reducing or eliminate particle contamination caused by the negatively charged species falling on the edge of the substrate when the electric power source 142 is turned off.

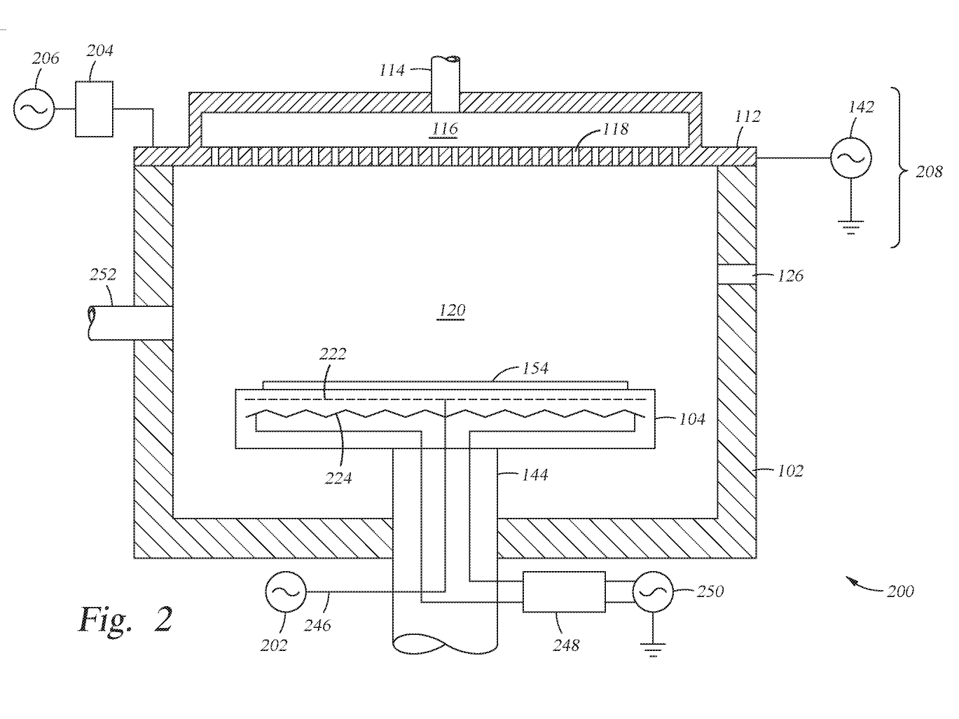

FIG. 2 is a schematic cross-sectional view of a plasma process chamber 200 according to another embodiment described herein. The process chamber 200 includes the chamber body 102, the substrate support 104 disposed inside the chamber body 102, and a lid assembly 208 coupled to the chamber body 102 and enclosing the substrate support 104 in the processing region 120. The lid assembly 208 may not include the electrode 108 and the isolator 110 shown in FIG. 1. The electric power source 142 is coupled to the gas distributor 112. A second electrical power source 206 may be coupled to the gas distributor 112 in addition to the electric power source 142. The second electric power source 206 may be an RF generator, and a filter 204 may be located between the second electric power source 206 and the gas distributor 112. The second electric power source 206 may be a DC power source and may be directly connected to the gas distributor 112. Substrates 154 are provided to the processing region 120 through the opening 126 formed in the chamber body 102.

The process chamber 200 includes the substrate support 104 and the shaft 144. A first electrode 222 may be embedded in the substrate support 104 or coupled to a surface of the substrate support 104. The first electrode 222 may be a plate, a perforated plate, a mesh, a wire screen, or any other distributed arrangement. The second electrode 222 is coupled to an electric power source 202 via a connection 246. The electric power source 202 may be an RF generator, and the electric power source 202 may be utilized to control properties of the plasma formed in the processing region 120. For example, the electric power source 142 and the electric power source 202 may be tuned to two different frequencies to promote ionization of multiple species in the processing region 120. An exhaust 252 is formed in the chamber body 102 at a location above the substrate support 104. The exhaust 252 may be connected to a vacuum pump (not shown) to remove unreacted species and by-products from the processing chamber 100.

A second electrode 224 may be embedded in the substrate support 104 or coupled to a surface of the substrate support 104. The second electrode 224 may be located below the first electrode 222, as shown in FIG. 2, or above the first electrode 222. The second electrode 224 may be a plate, a perforated plate, a mesh, a wire screen, or any other distributed arrangement. The second electrode 224 is connected to an electric power source 250. The electric power source 250 may be an RF generator, and a filter 248 may be located between the electric power source 250 and the second electrode 224. The electric power source 250 may be a DC power source and may be directly connected to the second electrode 224.

The substrate support 104 including the electrodes 222, 224 shown in FIG. 2 may be used with any processing chamber for plasma processing. Chambers from other manufacturers may also be used with the components described above.

FIG. 3 is a flow chart of a method 300 for reducing particle contamination in a plasma processing chamber according to one embodiment described herein. The method 300 starts at block 302, which is forming a plasma region in a processing region of a process chamber. The plasma region may be the plasma region 150, the processing region may be the processing region 120, and the process chamber may be the process chamber 100 shown in FIG. 1. Next, at block 304, the boundary of the plasma region is extended to be outside of a diameter of a substrate support. The substrate support may be the substrate support 104 shown in FIG. 1, and the diameter may be the diameter D1. The boundary of the plasma region is extended by applying a DC power from a DC power source to an electrode, such as applying a DC power from the DC power source 128 to the electrode 108 shown in FIG. 1. The DC power applied to the electrode may range from about −50 V to about −150 V. The DC power applied the electrode pulls the plasma region closer to the chamber body 102 (FIG. 1), causing a distance D2 (FIG. 1) between locations on the boundary of the plasma region closest to the chamber body 102 to be greater than the diameter of the substrate support. Because the distance D2 is greater than the diameter of the substrate support, any species, including the negatively charged species, located at the boundary of the plasma region will fall to a location below the substrate support and will be removed from the process chamber by an exhaust, for example, the exhaust 152 shown in FIG. 1. The DC power may be applied to the electrode at a time near the end of the operation, such as less than about 10 to 60 seconds before an electric power source utilized to form a plasma region in the processing region, such as the electric power source 142 shown in FIG. 1, is turned off. By applying a DC power to an electrode surrounding a processing region, the boundary of the plasma region formed in the processing region is extended closer to the chamber body and outside of the diameter of the substrate support. As a result, species located at the boundary of the plasma region will not fall onto the edge of the substrate disposed on the substrate support as the electric power for sustaining the plasma region is turned off, leading to reduced particle contamination on the substrate.

FIG. 4 is a flow chart of a method 400 for reducing particle contamination in a plasma process chamber according to another embodiment described herein. The method 400 starts at block 402, which is forming a plasma region in a processing region of a process chamber. The plasma region may be the plasma region 150, the processing region may be the processing region 120, and the process chamber may be the process chamber 100 shown in FIG. 1. Next, at block 404, a negative bias is applied to an electrode embedded in a substrate support. The electrode may be the second electrode 224 and the substrate support may be the substrate support 104 shown in FIG. 2. The negative bias may be applied by the electric power source 250 shown in FIG. 2. The negative bias may range from about −250 V to about −1000 V. The negative bias creates an upward force on the negatively charged species located at the boundary of the plasma region when the electric power utilized to create and sustain the plasma region is turned off. The electric power utilized to create and sustain the plasma region may be supplied from an electric power source, such as the electric power source 142 shown in FIG. 2. The negative bias may be applied to the electrode during the operation since the force created by the negative bias is minimal relative to the force created by the electric field that creates the plasma region. When the electric field disappears as the electric power utilized to sustain the plasma region is turned off, the force created by the negative bias prevents the negatively charged species located at the boundary of the plasma region from being attracted by the positively charged layer deposited on the substrate.

Alternatively, as shown at block 406, a positive bias is applied to a lid in addition to an electric power supplied to the lid. The lid may be any component of the lid assembly 208 shown in FIG. 2. In one embodiment, the positive bias is applied to a gas distributor, such as the gas distributor 112 shown in FIG. 2. The positive bias may be applied by the electric power source 206 shown in FIG. 2. The positive bias may range from about 250 V to about 1000 V. The positive bias creates an upward force on the negatively charged species located at the boundary of the plasma region when the electric power utilized to create and sustain the plasma region is turned off. The electric power utilized to create and sustain the plasma region may be supplied from an electric power source, such as the electric power source 142 shown in FIG. 2. The positive bias may be applied to the lid during the operation since the force created by the positive bias is minimal relative to the force created by the electric field that creates the plasma region. When the electric field disappears as the electric power utilized to sustain the plasma region is turned off, the force created by the positive bias prevents the negatively charged species located at the boundary of the plasma region from being attracted by the positively charged layer deposited on the substrate.

Next, at block 408, the negative bias applied to the electrode or the positive bias applied to the lid is continued after the electric power for sustaining the plasma region is turned off. The negatively charged species are prevented from being attracted by the positively charged layer deposited on the substrate and are removed from the process chamber by an exhaust, for example, the exhaust 252 shown in FIG. 2.

By applying a negative bias to an electrode or a positive bias to the lid, negatively charged species located at the boundary of the plasma region are lifted by the electrostatic force created by the negative bias or the positive bias. As a result, negatively charged species located at the boundary of the plasma region will not fall onto the edge of the substrate disposed on the substrate support as the electric power for sustaining the plasma region is turned off, leading to reduced particle contamination on the substrate.

While the foregoing is directed to embodiments of the present disclosure, other and further embodiments of the disclosure may be devised without departing from the basic scope thereof.

1. A method, comprising:
forming a plasma region in a processing region of a process chamber; and
extending a boundary of the plasma region to be outside of a diameter of a substrate support by biasing an electrode disposed radially outward of the plasma region.

2. The method of claim 1, wherein the extending a boundary of the plasma region comprises applying a DC power to the electrode.

3. The method of claim 2, wherein the DC power ranges from about −50 V to about −150 V.

4. The method of claim 3, wherein the DC power is applied to the electrode before an electric power source utilized to form the plasma region is turned off.

5. The method of claim 4, wherein the DC power is applied to the electrode less than about 10 to 60 seconds before the electric power source is turned off.

6. The method of claim 4, wherein the forming a plasma region comprises supplying one or more process gases to the process chamber via a gas distributor, and supplying electric power to the gas distributor from the electric power source.

7. A method, comprising:
forming a plasma region in a processing region of a process chamber;
applying a negative bias to a first electrode embedded in a substrate support; and
continuing the negative bias to the first electrode after an electric power utilized to sustain the plasma region is turned off.

8. The method of claim 7, wherein the negative bias ranges from about −1000 V to about −250 V.

9. The method of claim 7, further comprising applying RF power to a second electrode embedded in the substrate support.

10. The method of claim 9, wherein the first electrode is disposed below the second electrode.

11. The method of claim 9, wherein the first electrode is disposed above the second electrode.

12. The method of claim 7, wherein the first electrode comprises a plate, a perforated plate, a mesh, or a wire screen.

13. The method of claim 7, wherein the negative bias is supplied by an RF power source.

14. The method of claim 7, wherein the negative bias is supplied by a DC power source.

15. A method, comprising:
forming a plasma region in a processing region of a process chamber;
applying a positive bias to a lid; and
continuing the positive bias to the lid after an electric power utilized to sustain the plasma region is turned off.

16. The method of claim 15, wherein the positive bias ranges from about 250 V to about 1000 V.

17. The method of claim 15, wherein the electric power is supplied to the lid.

18. The method of claim 17, wherein the electric power is RF power.

19. The method of claim 17, wherein the electric power is DC power.

20. The method of claim 15, wherein the positive bias is supplied by a DC power source.
